(19) United States
(12) Patent Application Publication
(10) Pub. No.: US 2026/0305500 A1
(43) Pub. Date: Oct. 1, 2026

(54) METHOD FOR MANUFACTURING SEMICONDUCTOR DEVICE, AND SEMICONDUCTOR DEVICE

(71) Applicant: Resonac Corporation, Minato-ku, Tokyo (JP)

(72) Inventors: Toshiaki SHIRASAKA, Tokyo (JP); Tomoaki SHIBATA, Tokyo (JP); Tadashi OKUDA, Tokyo (JP); Shizu FUKUZUMI, Tokyo (JP)

(21) Appl. No.: 19/478,274

(22) PCT Filed: Nov. 13, 2023
(86) PCT No.: PCT/JP2023/040801

§ 371 Date: Oct. 24, 2025

(51) Int. Cl. H10W 90/00; H10W 72/90; H10W 80/00; H10W 90/26

(52) U.S. Cl. CPC H10W 90/792; H10W 72/932; H10W 72/936; H10W 72/963; H10W 72/967; H10W 80/163; H10W 80/312; H10W 80/314; H10W 80/327; H10W 90/26

(57) ABSTRACT

A method for bonding a first semiconductor substrate 100 (semiconductor chip) to a second semiconductor substrate 200 (semiconductor wafer) by hybrid bonding is disclosed. The first semiconductor substrate 100 includes an organic insulating film 102, electrodes 103, and dummy electrodes 104. The second semiconductor substrate 200 includes an organic insulating film 202 and electrodes 203. In this method, after the electrodes 103 and 203 are aligned, the organic insulating films 102 and 202 are bonded to each other, and the electrodes 103 and 203 are bonded to each other. In this hybrid bonding, a dummy electrode 104 protruding more than the terminal electrode 103 is provided on the first semiconductor substrate 100. A tip of the dummy electrode 104 is embedded in the organic insulating film 202 of the second semiconductor substrate 200. This ensures reliable bonding of the semiconductor substrates and improves the manufacturing yield.

### TECHNICAL FIELD

The present disclosure relates to a method for manufacturing a semiconductor device, and a semiconductor device.

### BACKGROUND ART

In recent years, three-dimensional integration technology has been studied to improve the degree of integration of LSIs. Non Patent Literature 1 discloses an example of a three-dimensional integration technology for semiconductor chips.

### CITATION LIST

### Non Patent Literature

Non Patent Literature 1: F.C. Chen et al., “System on Integrated Chips (SoIC™) for 3D Heterogeneous Integration”, 2019 IEEE 69th Electronic Components and Technology Conference (ECTC), p. 594-599(2019)

### SUMMARY OF INVENTION

### Technical Problem

As a three-dimensional integration technology for semiconductors, the use of hybrid bonding for Wafer-to-Wafer (W2W) bonding or Chip-on-Wafer (CoW) bonding is being considered. In hybrid bonding, an organic insulating material may be used for the insulating film at the connection interface as a countermeasure against foreign matter. In this case, since the coefficient of thermal expansion (CTE) of the organic insulating film is higher than that of the metal material (e.g., copper) of the terminal electrodes, the terminal electrodes are configured to protrude from the organic insulating film in consideration of heating during bonding. However, when semiconductor members having such a configuration are bonded to each other, the protruding terminal electrodes contact each other first, making it difficult for the insulating films to contact each other. For this reason, misalignment or detachment may occur in the bonding of the terminal electrodes during temporary pressure bonding. This may prevent the terminal electrodes and the insulating films from being reliably bonded to each other, resulting in a decrease in manufacturing yield.

An object of the present disclosure is to provide a method for manufacturing a semiconductor device, and a semiconductor device, which can reliably bond semiconductor substrates to each other and improve the manufacturing yield in hybrid bonding using an organic insulating film on at least one side.

### Solution to Problem

[1] The present disclosure, as one aspect, relates to a method for manufacturing a semiconductor device. This method for manufacturing a semiconductor device includes: preparing a first semiconductor substrate including a first substrate body, a first insulating film provided on a surface of the first substrate body, and at least one first electrode and at least one first dummy electrode that are provided on the surface of the first substrate body; preparing a second semiconductor substrate including a second substrate body, a second insulating film provided on a surface of the second substrate body, and at least one second electrode provided on the surface of the second substrate body; arranging the first semiconductor substrate and the second semiconductor substrate such that the first insulating film and the second insulating film face each other and the first electrode and the second electrode are aligned; bonding the first insulating film and the second insulating film to each other; and bonding the first electrode and the second electrode to each other. The second insulating film is an organic insulating film. In this manufacturing method, the first dummy electrode is configured to be at least partially embedded in the second insulating film.

In this method for manufacturing a semiconductor device, at least one first dummy electrode is provided on the surface of the first substrate body of the first semiconductor substrate. This first dummy electrode is configured to be at least partially embedded in the second insulating film, which is an organic insulating film. Such a first dummy electrode and the second insulating film prevent the occurrence of misalignment and detachment in the bonding of the terminal electrodes, and the first semiconductor substrate and the second semiconductor substrate are reliably bonded. Therefore, according to this manufacturing method, it is possible to reliably bond the terminal electrodes to each other and to reliably bond the insulating films to each other, and thus improve the manufacturing yield.
[2] In the method for manufacturing a semiconductor device of [1] above, it is preferable that a protrusion height of the first dummy electrode from a surface of the first insulating film is greater than a first protrusion height of the first electrode from the surface of the first insulating film. This ensures that the first dummy electrode is reliably embedded in the second insulating film. Therefore, according to this manufacturing method, the first semiconductor substrate and the second semiconductor substrate are reliably bonded, and the manufacturing yield is improved.
[3] In the method for manufacturing a semiconductor device of [1] or [2] above, it is preferable that a protrusion height of the first dummy electrode from a surface of the first insulating film is equal to or greater than a sum of a first protrusion height of the first electrode from the surface of the first insulating film and a second protrusion height of the second electrode from a surface of the second insulating film. This allows the first dummy electrode to contact the second insulating film and be embedded in the second insulating film before the first electrode and the second electrode contact each other and cause misalignment. Therefore, according to this manufacturing method, the first semiconductor substrate and the second semiconductor substrate are reliably bonded, and the manufacturing yield is improved.
[4] In the method for manufacturing a semiconductor device of any one of [1] to [3] above, it is preferable that a protrusion height of the first dummy electrode from a surface of the first insulating film is smaller than a thickness of the second insulating film. This prevents the protrusion height of the first dummy electrode from becoming too high and inhibiting the bonding between the first electrode and the second electrode. Therefore, according to this manufacturing method, the first electrode and the second electrode are reliably bonded, and the manufacturing yield is improved.
[5] In the method for manufacturing a semiconductor device of any one of [1] to [4] above, a protrusion height of the first dummy electrode from a surface of the first insulating film may be from 0.02 μm to 5 μm. When the protrusion height of the first dummy electrode is 0.02 μm or more, the first dummy electrode is reliably embedded in the second insulating film. On the other hand, when the protrusion height of the first dummy electrode is 5 μm or less, it is prevented that the protrusion height becomes too high and inhibits the bonding between the first electrode and the second electrode. Therefore, according to this manufacturing method, the first semiconductor substrate and the second semiconductor substrate are reliably bonded, and the first electrode and the second electrode are reliably bonded, thereby improving the manufacturing yield.
[6] In the method for manufacturing a semiconductor device of any one of [1] to [5] above, it is preferable that when aligning the first electrode and the second electrode, the first dummy electrode contacts the second insulating film before the first electrode and the second electrode contact each other. This allows the first dummy electrode to contact the second insulating film and be embedded in the second insulating film before the first electrode and the second electrode contact each other and cause misalignment. Therefore, according to this manufacturing method, the first semiconductor substrate and the second semiconductor substrate are reliably bonded, and the manufacturing yield is improved.
[7] In the method for manufacturing a semiconductor device of any one of [1] to [6] above, in the preparing the first semiconductor substrate, the first dummy electrode is formed from the same metal material as the first electrode, and the first electrode and the first dummy electrode may be polished such that the first dummy electrode protrudes more than the first electrode. This allows the protrusion height of the first dummy electrode to be formed by a simple means. In addition, the first dummy electrode and the first electrode before polishing can be manufactured by the same method, which improves manufacturing efficiency.
[8] In the method for manufacturing a semiconductor device of any one of [1] to [6] above, in the preparing the first semiconductor substrate, a metal material may be added on a main body of the first dummy electrode such that the first dummy electrode protrudes more than the first electrode. This allows the protrusion height of the first dummy electrode to be formed by a simple means. In addition, the first dummy electrode before adding the metal material and the first electrode can be manufactured by the same method, which improves manufacturing efficiency.
[9] In the method for manufacturing a semiconductor device of any one of [1] to [8] above, a region of the second insulating film facing the first dummy electrode may be formed to be thicker than other regions of the second insulating film. This allows the first dummy electrode to contact the second insulating film earlier, and the first dummy electrode is reliably embedded in the second insulating film. Therefore, according to this manufacturing method, the first semiconductor substrate and the second semiconductor substrate are reliably bonded, and the manufacturing yield is improved.
[10] In the method for manufacturing a semiconductor device of any one of [1] to [9] above, it is preferable that the at least one first dummy electrode includes a plurality of first dummy electrodes. Such a plurality of first dummy electrodes and the second insulating film allow the first semiconductor substrate and the second semiconductor substrate to be more reliably bonded, improving the manufacturing yield.
[11] In the method for manufacturing a semiconductor device of [10] above, the at least one first electrode may include a plurality of first electrodes, and the plurality of first electrodes may be located between the plurality of dummy electrodes. In this case, the dummy electrodes are arranged on the outside, which facilitates the design of the electric circuit including the first electrodes and the like on the inside. In addition, by arranging the dummy electrodes on the outside, stress applied to the dummy electrodes when a rotational stress is applied to the semiconductor substrate or the semiconductor chip can be reduced, and detachment of the chip or the like can be prevented. Furthermore, by arranging the dummy electrodes on the outside, misalignment in the rotational direction can be easily detected by the dummy electrodes when it occurs, so the dummy electrodes can also serve as alignment marks. It should be noted that stress and deformation such as warpage can also be prevented.
[12] In the method for manufacturing a semiconductor device of any one of [1] to [11] above, it is preferable that the first dummy electrode is an alignment mark configured to align the first electrode and the second electrode. This eliminates the need for a space to provide dummy electrodes individually, and improves the mounting density of wiring electrodes on the semiconductor substrate.
[13] In the method for manufacturing a semiconductor device of any one of [1] to [12] above, a planar shape of the first dummy electrode may be a cross shape, a ring shape, a circular shape, or a polygonal shape. When the dummy electrode has such a shape, misalignment in the vertical, horizontal, and rotational directions of the semiconductor substrate or semiconductor chip can be detected sensitively and quantitatively.
[14] In the method for manufacturing a semiconductor device of any one of [1] to [13] above, the second semiconductor substrate may have at least one second dummy electrode provided on the surface of the second substrate body, and the first dummy electrode and the second dummy electrode may have planar shapes that are complementary to each other. By aligning the first semiconductor substrate and the second semiconductor substrate using such a first dummy electrode and a second dummy electrode, the alignment of both becomes easy.
[15] In the method for manufacturing a semiconductor device of [14] above, the first insulating film of the first semiconductor substrate may be an organic insulating film, and the second dummy electrode may be configured to be at least partially embedded in the first insulating film. By thus providing dummy electrodes on both semiconductor substrates and configuring them to be embedded in the insulating films, the first semiconductor substrate and the second semiconductor substrate are more reliably bonded, and the manufacturing yield is further improved.

The present disclosure, as another aspect, relates to a semiconductor device. This semiconductor device includes a first semiconductor substrate and a second semiconductor substrate. The first semiconductor substrate includes a first substrate body, a first insulating film provided on a surface of the first substrate body, and at least one first electrode and at least one first dummy electrode that are provided on the surface of the first substrate body. The second semiconductor substrate includes a second substrate body, a second insulating film provided on a surface of the second substrate body, and at least one second electrode provided on the surface of the second substrate body. In this semiconductor device, the first insulating film and the second insulating film are bonded to each other, and the first electrode and the second electrode are bonded to each other. The second insulating film is an organic insulating film. In this semiconductor device, the first dummy electrode is configured to be at least partially embedded in the second insulating film.

In this semiconductor device, at least one first dummy electrode is provided on the surface of the first substrate body of the first semiconductor substrate. This first dummy electrode is configured to be at least partially embedded in the second insulating film, which is an organic insulating film. With such a first dummy electrode and the second insulating film, the first semiconductor substrate and the second semiconductor substrate are reliably bonded.

### Advantageous Effects of Invention

According to the present disclosure, in hybrid bonding using an organic insulating film on at least one side, it is possible to reliably bond semiconductor substrates to each other and improve the manufacturing yield.

### BRIEF DESCRIPTION OF DRAWINGS

FIG. 1 is a cross-sectional view schematically showing an example of a semiconductor device manufactured by a method for manufacturing a semiconductor device according to an embodiment of the present disclosure.

FIG. 2(a) to (c) of FIG. 2 are schematic cross-sectional views sequentially showing a method for manufacturing the semiconductor device shown in FIG. 1.

FIG. 3(a) of FIG. 3 is an enlarged cross-sectional view of a part of (a) of FIG. 2, and (b) of FIG. 3 is an enlarged cross-sectional view of a part of (b) of FIG. 2.

FIG. 4 is a partially cutaway perspective view showing a state in which a dummy electrode is embedded in an organic insulating film.

FIG. 5(a) of FIG. 5 is a plan view showing a first modification example (alignment mark) of a dummy electrode, (b) of FIG. 5 is a cross-sectional view taken along line Vb-Vb in (a) of FIG. 5, and (c) of FIG. 5 is a cross-sectional view taken along line Vc-Vc in (a) of FIG. 5.

FIG. 6(a) of FIG. 6 is a plan view showing an example of a dummy electrode having a shape complementary to the dummy electrode shown in FIG. 5, and (b) of FIG. 6 is a cross-sectional view taken along VIb-VIb in (a) of FIG. 6.

FIG. 7 is a plan view showing a state in which the dummy electrode shown in FIG. 5 and the dummy electrode shown in FIG. 6 are overlapped.

FIGS. 8(a) and (b) of FIG. 8 are plan views showing an example in which the first modification example of the dummy electrodes are provided at the four corners of each semiconductor substrate, and (c) of FIG. 8 is a plan view showing a state in which the dummy electrodes shown in (a) of FIG. 8 and the dummy electrodes shown in (b) of FIG. 8 are overlapped.

FIGS. 9(a) and (b) of FIG. 9 are plan views showing a second modification example (alignment mark) of dummy electrodes.

FIG. 10(a) of FIG. 10 is a plan view showing a state in which the dummy electrode shown in (a) of FIG. 9 and the dummy electrode shown in (b) of FIG. 9 are overlapped. (b) of FIG. 10 is a plan view showing a third modification example (alignment mark) of a dummy electrode, and is a plan view showing a state in which the dummy electrode shown in (a) of FIG. 9 and a cross-shaped dummy electrode are overlapped.

FIGS. 11(a) and (b) of FIG. 11 are plan views showing an example in which the second modification example of the dummy electrodes are provided at two points on a diagonal line of each semiconductor substrate, and (c) of FIG. 11 is a plan view showing a state in which the dummy electrodes shown in (a) of FIG. 11 and the dummy electrodes shown in (b) of FIG. 11 are overlapped.

### DESCRIPTION OF EMBODIMENTS

Hereinafter, some embodiments of the present disclosure will be described in detail with reference to the drawings as necessary. In the following description, the same or corresponding parts are denoted by the same reference signs, and redundant description is omitted. In addition, positional relationships such as up, down, left, and right are based on the positional relationships shown in the drawings unless otherwise specified. When terms such as “left,” “right,” “front,” “back,” “top,” “bottom,′ “upper,” and “lower” are used in the description of this specification and the claims, they are for the purpose of explanation and do not necessarily mean that they are permanently in this relative position. Furthermore, the dimensional ratios in the drawings are not limited to the illustrated ratios.

In this specification, the term “layer” or “film” includes not only a structure having a shape formed over the entire surface but also a structure having a shape formed in a part thereof when observed as a plan view. In this specification, the term “step” is included in this term not only as an independent step but also if the intended action of the step is achieved even when it cannot be clearly distinguished from other steps. A numerical range indicated using “to” indicates a range including the numerical values described before and after “to” as the minimum value and the maximum value, respectively.

### (Configuration of Semiconductor Device)

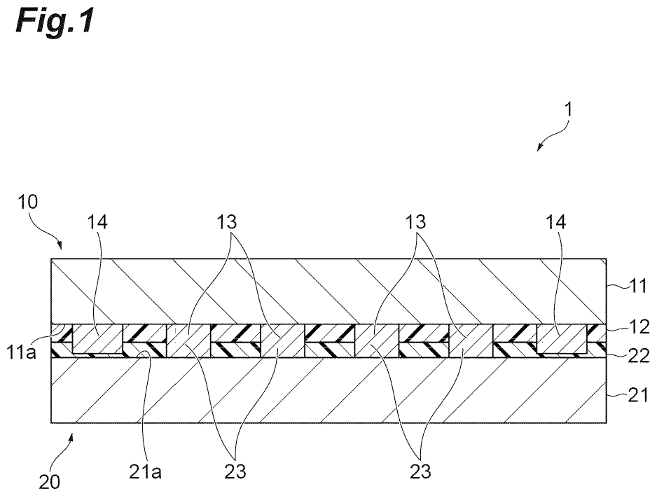

FIG. 1 is a cross-sectional view schematically showing an example of a semiconductor device manufactured by a method for manufacturing a semiconductor device according to an embodiment. As shown in FIG. 1, a semiconductor device 1 includes a first semiconductor substrate 10 and a second semiconductor substrate 20. The first semiconductor substrate 10 includes a substrate body 11 (first substrate body), an insulating film 12 (first insulating film) provided on a surface 11a of the substrate body 11, and a plurality of terminal electrodes 13 (first electrode) and dummy electrodes 14 (first dummy electrode) that are provided on the surface 11a of the substrate body 11. The second semiconductor substrate 20 includes a substrate body 21 (second substrate body), an insulating film 22 (second insulating film) provided on a surface 21a of the substrate body 21, and a plurality of terminal electrodes 23 (second electrode) provided on the surface 21a of the substrate body 21. In the semiconductor device 1, the insulating film 12 and the insulating film 22 are bonded to each other to form one insulating film. Also, each of the terminal electrodes 13 and each of the terminal electrodes 23 are bonded to each other, each forming one terminal electrode. The terminal electrodes 13 and 23 are formed from a metal material such as copper. The insulating film 12 and the insulating film 22 are organic insulating films, and are formed, for example, from polyimide (PI), which is an organic insulating material. In such an insulating film 22, a tip (a lower portion in FIG. 1) of the dummy electrode 14, which protrudes downward (toward the second semiconductor substrate 20) more than the terminal electrode 13, is configured to be embedded. As a result, the first semiconductor substrate 10 and the second semiconductor substrate 20 are firmly bonded. The insulating film 12 on the side where the dummy electrode 14 is provided is preferably an organic insulating film, but may be an inorganic insulating film such as SiO₂. The insulating film 22 is mainly formed from an organic insulating film, but may include an inorganic insulating film in a part thereof.

The first semiconductor substrate 10 and the second semiconductor substrate 20 constituting such a semiconductor device 1 may be semiconductor chips or semiconductor wafers. For example, when the first semiconductor substrate 10 is a semiconductor chip and the second semiconductor substrate 20 is a semiconductor wafer, a Chip-on-wafer (CoW) structure is formed. In this case, the second semiconductor substrate 20 may be, for example, a substrate on which a plurality of semiconductor chips such as Large Scale Integrated Circuit (LSI) chips or Complementary Metal Oxide Semiconductor (CMOS) sensors are formed at locations corresponding to the semiconductor chip (first semiconductor substrate 10), but is not limited thereto. The first semiconductor substrate 10, which is a semiconductor chip, may be, for example, a semiconductor chip such as an LSI or a memory, but is not limited thereto. Note that both the first semiconductor substrate 10 and the second semiconductor substrate 20 may be semiconductor wafers, and in this case, a Wafer-to-Wafer (W2W) structure is formed. The first semiconductor substrate 10 and the second semiconductor substrate 20 are finely bonded by a later-described hybrid bonding manufacturing method using an organic insulating film and dummy electrodes, such that their respective terminal electrodes and the surrounding organic insulating films are firmly bonded without misalignment.

### (Method for Manufacturing Semiconductor Device)

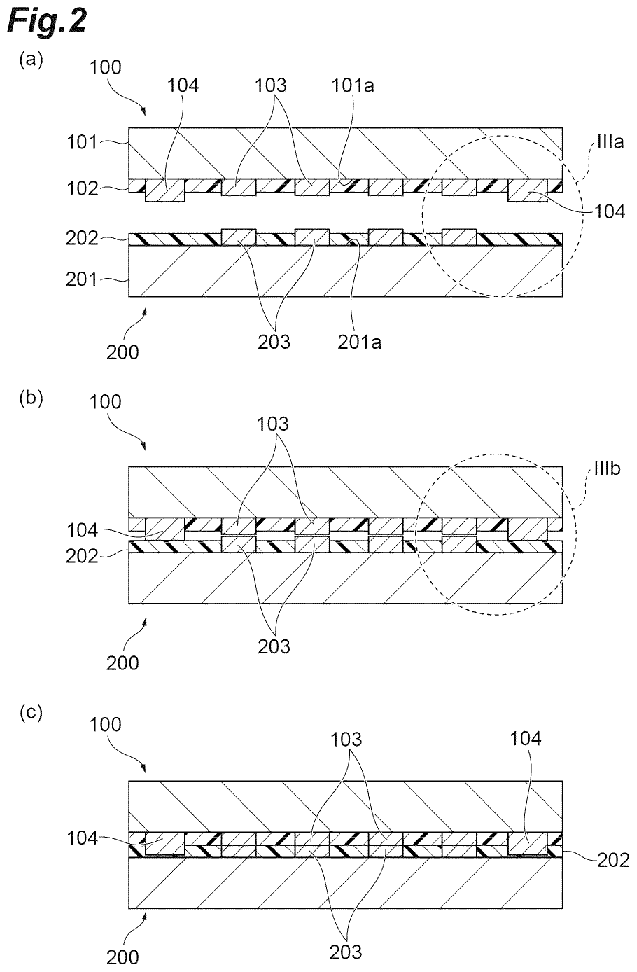

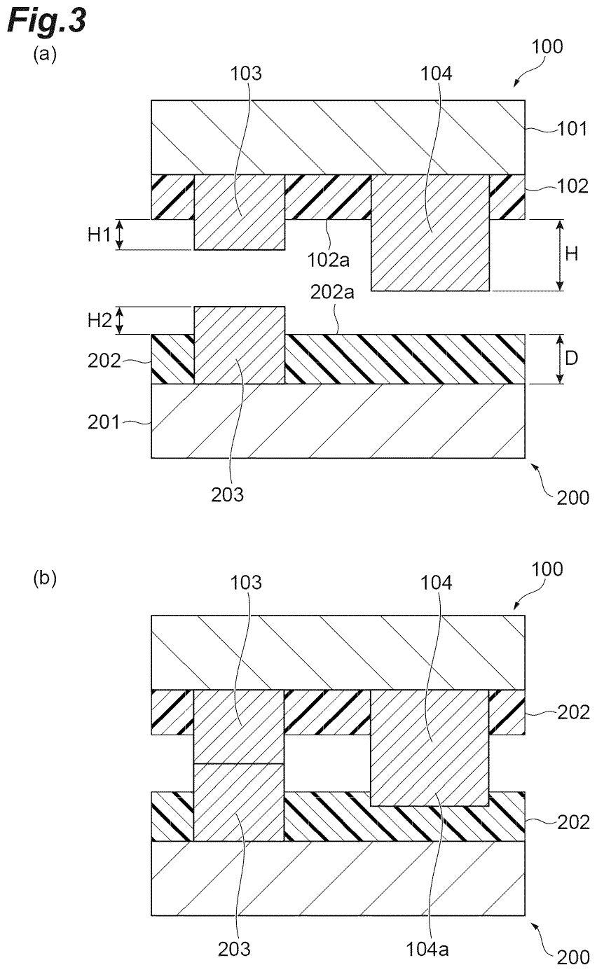

Next, a method for manufacturing the semiconductor device 1 will be described with reference to FIG. 2 and FIG. 3. (a) to (c) of FIG. 2 are schematic cross-sectional views sequentially showing a method for manufacturing the semiconductor device 1 shown in FIG. 1. (a) of FIG. 3 is an enlarged cross-sectional view of a part of (a) of FIG. 2, and (b) of FIG. 3 is an enlarged cross-sectional view of a part of (b) of FIG. 2.

The semiconductor device 1 can be manufactured, for example, through the following steps (a) to (e).
(a) A step of preparing a first semiconductor substrate including a first substrate body, a first insulating film provided on a surface of the first substrate body, and at least one first electrode and at least one first dummy electrode that are provided on the surface of the first substrate body.
(b) A step of preparing a second semiconductor substrate having a second substrate body, a second insulating film provided on a surface of the second substrate body, and at least one second electrode provided on the surface of the second substrate body.
(c) A step of arranging the first semiconductor substrate and the second semiconductor substrate such that the first insulating film and the second insulating film face each other and the first electrode and the second electrode are aligned.
(d) A step of bonding the first insulating film and the second insulating film to each other.
(e) A step of bonding the first electrode and the second electrode to each other.
   [Step (a)]

Step (a) is a step of preparing a first semiconductor substrate 100, which is a silicon substrate on which an integrated circuit including semiconductor elements and wiring connecting them is formed. In step (a), as shown in (a) of FIG. 2, a plurality of terminal electrodes 103 made of copper or aluminum or the like are provided at a predetermined interval on a surface 101a of a substrate body 101 made of silicon or the like, and an insulating film 102 (first insulating film) made of an organic insulating material is provided. The thickness D of the insulating film 102 may be, for example, from 1 μm to 10 μm, and may be 5 μm or less. The terminal electrode 103 is an electrode for exposing an integrated circuit or the like formed on the first semiconductor substrate 100 to the outside through the insulating film 102. The plurality of terminal electrodes 103 may be provided after providing the insulating film 102 on the surface 101a of the substrate body 101, or the insulating film 102 may be provided after providing the plurality of terminal electrodes 103 on the surface 101a of the substrate body 101.

Further, in step (a), dummy electrodes 104 made of copper or aluminum or the like are further provided on the surface 101a of the substrate body 101. As shown in (a) of FIG. 3, the dummy electrodes 104 are formed such that each protrusion height H of the dummy electrodes 104 from a surface 102a of the insulating film 102 is greater than a protrusion height H1 (first protrusion height) of the terminal electrode 103 from the surface 102a of the insulating film 102. The protrusion height H of the dummy electrode 104 is, for example, preferably equal to or greater than a sum of the protrusion height H1 of the terminal electrode 103 from the surface 102a of the insulating film 102 and a protrusion height H2 (second protrusion height) of a later-described terminal electrode 203 from a surface 202a of an insulating film 202, and more preferably higher than the sum of the protrusion height H1 and the protrusion height H2. The protrusion height H of the dummy electrode 104 may be, for example, from 0.02 μm to 5 μm, preferably from 0.08 μm to 0.2 μm, and more preferably from 0.12 μm to 0.16 μm. The protrusion height H1 of the terminal electrode 103 is, for example, preferably from 40 nm to 100 nm, and more preferably from 60 nm to 80 nm. Such dummy electrodes 104 are provided, for example, on the outside of the substrate body 101 so as to sandwich the plurality of terminal electrodes 103 therebetween. The dummy electrode 104 may be provided on the inside of the substrate body 101.

Note that the minimum height of the protrusion height H of the dummy electrode 104 described above may be calculated, for example, from the following formula (1).

$$\begin{matrix}[ Math . 1 ] & \\ H = {μ}_{a} + {μ}_{b} + 2 \sqrt{{σ}_{a}^{2} + {σ}_{b}^{2} + {σ}_{PI}^{2}} & ( 1 )\end{matrix}$$

Here, H is the protrusion height of the dummy electrode 104 from the surface 102a of the insulating film 102, Ha is the average height of the protrusion height H1 of the terminal electrodes 103 on the first semiconductor substrate 100 side where the dummy electrode 104 is provided from the surface of the insulating film 102, and μ_{b} is the average height of the protrusion height H2 of the terminal electrodes 203 on the second semiconductor substrate 200 side facing the dummy electrode 104 from the surface of the insulating film 202. Also, σₐ² is the variance of the protrusion height H1 of the terminal electrodes 103 from the surface of the insulating film 102, σ_{b}² is the variance of the protrusion height H2 of the terminal electrodes 203 from the surface of the insulating film 202, and σ_{PI}² is the variance of the thickness D of the insulating film 202 of the second semiconductor substrate 200.

The dummy electrode 104 can be formed, for example, as follows. First, on the surface 101a of the substrate body 101, metal portions that will become the terminal electrodes 103 and the dummy electrodes 104 are formed from the same material (e.g., copper), and the insulating film 102 is formed. Then, the surface of the metal portion and the surface of the insulating film 102 are polished and planarized by a polishing means using a Chemical Mechanical Polishing (CMP) method. During this planarization, in addition to changing the material composition or polishing rate of the slurry used in the CMP method, by making conditions different, such as making the metal portion of the dummy electrode 104 larger than the metal portion of the terminal electrode 103 (changing the size), or increasing the pad density around the metal portion of the dummy electrode 104 (changing the density), the protrusion height H of the dummy electrode 104 can be made higher than the protrusion height H1 of the terminal electrode 103. By such polishing, the terminal electrode 103 can be formed to slightly protrude from the surface 102a of the insulating film 102, and the dummy electrode 104 can be formed to protrude further than the terminal electrode 103. The surface roughness Ra of the insulating film 102 and the terminal electrode 103 after polishing may be 1 nm or less. As another method, on the surface 101a of the substrate body 101, metal portions that will become the terminal electrodes 103 and the dummy electrodes 104 are formed from the same material, and the insulating film 102 is formed. Then, the surface of the metal portion and the surface of the insulating film 102 are polished and planarized by a polishing means using CMP or the like. Thereafter, another metal material is deposited (added) by sputtering on the metal portion (main body) corresponding to the dummy electrode 104, so that the protrusion height H of the dummy electrode 104 can be formed to be higher than the protrusion height H1 of the terminal electrode 103.

[Step (b)]

Step (b) is a step similar to step (a), except that no dummy electrode is provided, and is a step of preparing a second semiconductor substrate 200, which is a silicon substrate on which an integrated circuit including semiconductor elements and wiring connecting them is formed. In step (b), as shown in (a) of FIG. 2, a plurality of terminal electrodes 203 made of copper or aluminum or the like are provided at a predetermined interval on a surface 201a of a substrate body 201 made of silicon or the like, and an insulating film 202 (second insulating film) made of an organic insulating material is provided. The terminal electrode 203 is an electrode for exposing an integrated circuit or the like formed on the second semiconductor substrate 200 to the outside through the insulating film 202. The plurality of terminal electrodes 203 may be provided after providing the insulating film 202 on the surface 201a of the substrate body 201, or the insulating film 202 may be provided after providing the plurality of terminal electrodes 203 on the surface 201a of the substrate body 201. The thickness D of the insulating film 202 may be, for example, from 1 μm to 10 μm, and may be 5 μm or less. In step (b) as well, it is preferable to perform polishing to planarize the surfaces of the insulating film 202 and the terminal electrodes 203. The surface roughness Ra of the insulating film 202 and the terminal electrodes 203 after polishing may be 1 nm or less.

The organic insulating material used for the insulating films 102 and 202 in step (a) and step (b) is, for example, polyimide, a polyimide precursor (e.g., polyamic ester or polyamic acid), polyamide-imide, bismaleimide, benzocyclobutene (BCB), polybenzoxazole (PBO), or a PBO precursor. These organic insulating materials have a lower elastic modulus than inorganic materials such as silicon oxide (SiO₂), for example, and are soft materials. By using such an organic insulating material, when the insulating films are bonded together in step (d) described later, even if there is fine debris on the insulating film, it can be absorbed into the insulating film to prevent bonding defects due to the debris, and the bonding of the insulating films can be reliably performed. For example, when the thickness of the insulating films 102 and 202 is 4 μm, debris with a diameter or width of 4 μm can be embedded in the organic insulating film. The elastic modulus of the organic insulating material constituting the insulating films 102 and 202 may be, for example, 7.0 GPa or less, may be 5.0 GPa or less, may be 3.0 GPa or less, may be 2.0 GPa or less, and may be 1.5 GPa or less. The elastic modulus here means Young's modulus. The organic insulating material constituting the insulating films 102 and 202 preferably has a coefficient of thermal expansion of 70 ppm/K or less, and more preferably may have 50 ppm/K or less.

Since the organic insulating materials used for the insulating films 102 and 202 are liquid or soluble in a solvent, each insulating film can be easily formed as a thin film by spin coating or the like. Furthermore, since these organic insulating materials have heat resistance, they can withstand the temperature (for example, a high temperature of 300° C. or higher) when bonding the terminal electrode 103 and the terminal electrode 203 in step (e) described later, so that the bonding between the insulating films is not deteriorated by the high temperature. As the organic insulating material constituting the insulating films 102 and 202, a photosensitive resin, a thermosetting non-conductive film (NCF), or a thermosetting resin may be used. This organic insulating material may be an underfill material. Note that the insulating film 102 on the side opposite to the side where the dummy electrodes 104 are embedded may be formed from an inorganic insulating material such as SiO₂. Also, the insulating film 202 on the side where the dummy electrode 104 is embedded is mainly formed from an organic insulating material, but may contain an inorganic insulating material to the extent that it does not inhibit the embedding of the dummy electrodes 104.

[Step (c)]

Subsequently, when the preparation of the first semiconductor substrate 100 and the second semiconductor substrate 200 is completed, as shown in (a) of FIG. 2, the first semiconductor substrate 100 and the second semiconductor substrate 200 are arranged such that the insulating film 102 and the insulating film 202 face each other and each terminal electrode 103 and each terminal electrode 203 are aligned to each other.

[Step (d)] and [Step (e)]

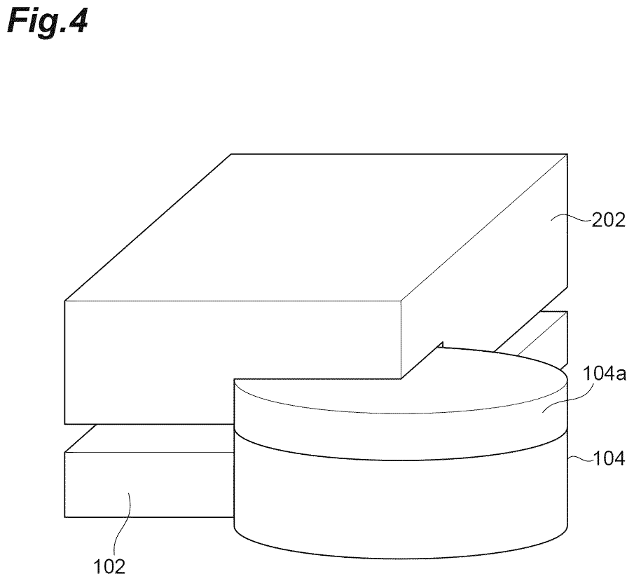

Subsequently, when each terminal electrode 203 of the second semiconductor substrate 200 is positioned with respect to each terminal electrode 103 of the first semiconductor substrate 100, as shown in (b) of FIG. 2, the first semiconductor substrate 100 is relatively moved and brought closer to the second semiconductor substrate 200. At this time, each tip of the dummy electrodes 104 of the first semiconductor substrate 100 comes into contact with the insulating film 202 of the second semiconductor substrate 200. At this stage, it is preferable that the terminal electrode 103 of the first semiconductor substrate 100 and the terminal electrode 203 of the second semiconductor substrate 200 are not in contact, and a gap is formed between both terminal electrodes. However, the terminal electrode 103 and the terminal electrode 203 may be in contact. In this state, the first semiconductor substrate 100 and the second semiconductor substrate 200 are heated to a predetermined high temperature, for example, 200° C. to 350° C. Thereafter, as shown in (b) of FIG. 3, the first semiconductor substrate 100 is pressed against the second semiconductor substrate 200 with a predetermined pressure (for example, 0.8 MPa), so that each tip 104a of the dummy electrodes 104 enters the insulating film 202, which has been softened by heating (see also FIG. 4, however, FIG. 4 is shown upside down). After each tip 104a of the dummy electrodes 104 enters the insulating film 202, each terminal electrode 103 of the first semiconductor substrate 100 and each terminal electrode 203 of the second semiconductor substrate 200 come into contact. By the dummy electrodes 104 entering the insulating film 202 in this way, the first semiconductor substrate 100 is positioned with respect to the second semiconductor substrate 200, and the two substrates are fixed.

Then, the above-described pressing process is continued for about one hour, for example, using a pressing member. Since the two substrates are fixed to each other by the dummy electrodes 104 entering the insulating film 202, misalignment or the like does not occur between the terminal electrodes 103 and the terminal electrodes 203 even if such a pressing process is performed. In addition, the above-described heating is maintained during this pressing process. During this heating process, in the first semiconductor substrate 100, the insulating film 102 thermally expands (the terminal electrodes 103 also thermally expand), and the surface of the insulating film 102 becomes substantially coincident with the surface of the terminal electrodes 103. Similarly, during this heating process, in the second semiconductor substrate 200, the insulating film 202 thermally expands (the terminal electrodes 203 also thermally expand), and the surface of the insulating film 202 becomes substantially coincident with the surface of the terminal electrodes 203. In this way, in the method for manufacturing a semiconductor device according to the present embodiment, hybrid bonding is performed in a state where the surface of the terminal electrodes 103 and the surface of the insulating film 102 substantially coincide, and the surface of the terminal electrodes 203 and the surface of the insulating film 202 substantially coincide, during heating. By being able to perform hybrid bonding in such a state, when bonding the insulating film 102 of the first semiconductor substrate 100 and the insulating film 202 of the second semiconductor substrate 200, the terminal electrodes 103 of the first semiconductor substrate 100 and the terminal electrodes 203 of the second semiconductor substrate 200 can be more reliably abutted and bonded. The bonding of the insulating films and the bonding of the electrodes may be performed simultaneously, or after the insulating films are bonded, the pressing may be further advanced to bond the electrodes. That is, step (d) and step (e) may be performed simultaneously, or step (e) may be performed while performing step (d). Through such bonding, the semiconductor device 1 shown in FIG. 1 is obtained.

When the electrodes are bonded by further advancing the pressing after the insulating films are bonded, in step (d), a step of performing temporary pressure bonding to bond the insulating film 102 and the insulating film 202 to each other, and a step of performing final pressure bonding to bond the terminal electrode 103 and the terminal electrode 203 to each other are performed. In this bonding method, it is preferable that, as described above, the dummy electrodes 104 enter the insulating film 202 and fixe the two substrates to each other at both the temporary pressure bonding and final pressure bonding stages. When performing temporary pressure bonding and final pressure bonding, the heating temperature and pressurization pressure in the temporary pressure bonding, and the heating temperature and pressurization pressure in the final pressure bonding may be different in both temperature and pressure, or may be partially different. For example, the heating temperature in the temporary pressure bonding may be from 150° C. to 400° C., and the heating temperature in the final pressure bonding may be from 200° C. to 350° C. The pressurization pressure in the temporary pressure bonding may be from 1 MPa to 6 MPa, and the pressurization pressure in the final pressure bonding may be from 1 MPa to 20 MPa.

The semiconductor device 1, which is composed of the first semiconductor substrate 100 and the second semiconductor substrate 200 bonded to each other by hybrid bonding in this manner, may be further singulated.

Here, the adhesion force of the dummy electrode 104 to the second semiconductor substrate 200 (insulating film 202) will be described with reference to FIG. 4. For example, if the diameter of the dummy electrode 104 is 10 μm, the bottom area of the dummy electrode 104 is 78.5 μm². On the other hand, the circumference of the dummy electrode 104 is 31.4 μm, and if the protrusion height H of the dummy electrode 104 is 50 μm, the side area of the dummy electrode 104 is 1.57 μm². From these values, it can be seen that the bottom area of the dummy electrode 104 is larger than the side area. That is, it can be seen that the magnitude of the adhesion force of the dummy electrode 104 is dominated by the size of the bottom area of the dummy electrode 104. If four such dummy electrodes 104 are provided on one semiconductor substrate, the adhesion force to the insulating film 202 formed of polyimide is, for example, 20 MPa. It is clear that with such an adhesion force, the first semiconductor substrate 100 is more reliably bonded and held to the second semiconductor substrate 200.

As described above, according to the method for manufacturing a semiconductor device of the present embodiment, the dummy electrode 104 is provided on the surface 101a of the substrate body 101 of the first semiconductor substrate 100. A part of this dummy electrode 104 is configured to be embedded in the insulating film 202, which is an organic insulating film. With such a dummy electrode 104 and the insulating film 202, the occurrence of misalignment and detachment in the bonding of the terminal electrodes is prevented, and the first semiconductor substrate 100 and the second semiconductor substrate 200 are reliably bonded. Therefore, according to this manufacturing method, it is possible to reliably bond the terminal electrodes to each other and to reliably bond the insulating films to each other, and thus improve the manufacturing yield.

In the method for manufacturing a semiconductor device according to the present embodiment, a protrusion height H of the dummy electrode 104 from the surface 102a of the insulating film 102 is greater than a protrusion height H1 of the terminal electrode 103 from the surface 102a of the insulating film 102. This ensures that the dummy electrode 104 is reliably embedded in the insulating film 202. Therefore, according to this manufacturing method, the first semiconductor substrate 100 and the second semiconductor substrate 200 are reliably bonded, and the manufacturing yield is improved.

In the method for manufacturing a semiconductor device according to the present embodiment, the protrusion height H of the dummy electrode 104 is equal to or greater than a sum of the protrusion height H1 of the terminal electrode 103 and a protrusion height H2 of the terminal electrode 203 from the surface 202a of the insulating film 202. This allows the dummy electrode 104 to contact the insulating film 202 and be embedded in the insulating film 202 before the terminal electrode 103 and the terminal electrode 203 contact each other and cause misalignment.

Therefore, according to this manufacturing method, the first semiconductor substrate 100 and the second semiconductor substrate 200 are reliably bonded, and the manufacturing yield is improved.

In the method for manufacturing a semiconductor device according to the present embodiment, the protrusion height H of the dummy electrode 104 is smaller than a thickness D of the insulating film 202. This prevents the protrusion height H of the dummy electrode 104 from becoming too high and inhibiting the bonding between the terminal electrode 103 and the terminal electrode 203. Therefore, according to this manufacturing method, the terminal electrode 103 and the terminal electrode 203 are reliably bonded, and the manufacturing yield is improved.

In the method for manufacturing a semiconductor device according to the present embodiment, when aligning the terminal electrode 103 and the terminal electrode 203, the dummy electrode 104 contacts the insulating film 202 before the terminal electrode 103 and the terminal electrode 204 contact each other. This allows the dummy electrode 104 to contact the insulating film 202 and be embedded in the insulating film 202 before the terminal electrode 103 and the terminal electrode 204 contact each other and cause misalignment. Therefore, according to this manufacturing method, the first semiconductor substrate 100 and the second semiconductor substrate 200 are reliably bonded, and the manufacturing yield is improved.

In the method for manufacturing a semiconductor device according to the present embodiment, when preparing the first semiconductor substrate 100, the dummy electrode 104 is formed from the same metal material as the terminal electrode 103, and the terminal electrode 103 and the dummy electrode 104 may be polished such that the dummy electrode 104 protrudes more than the terminal electrode 103. This allows the protrusion height H of the dummy electrode 104 to be formed by a simple means. In addition, the dummy electrode 104 and the terminal electrode 103 before polishing can be manufactured by the same method, which improves manufacturing efficiency.

In the method for manufacturing a semiconductor device according to the present embodiment, when preparing the first semiconductor substrate 100, a metal material may be added on a main body of the dummy electrode 104 such that the dummy electrode 104 protrudes more than the terminal electrode 103. This allows the protrusion height H of the dummy electrode 104 to be formed by a simple means. In addition, the dummy electrode 104 before adding the metal material and the terminal electrode 103 can be manufactured by the same method, which improves manufacturing efficiency.

### First Modification Example

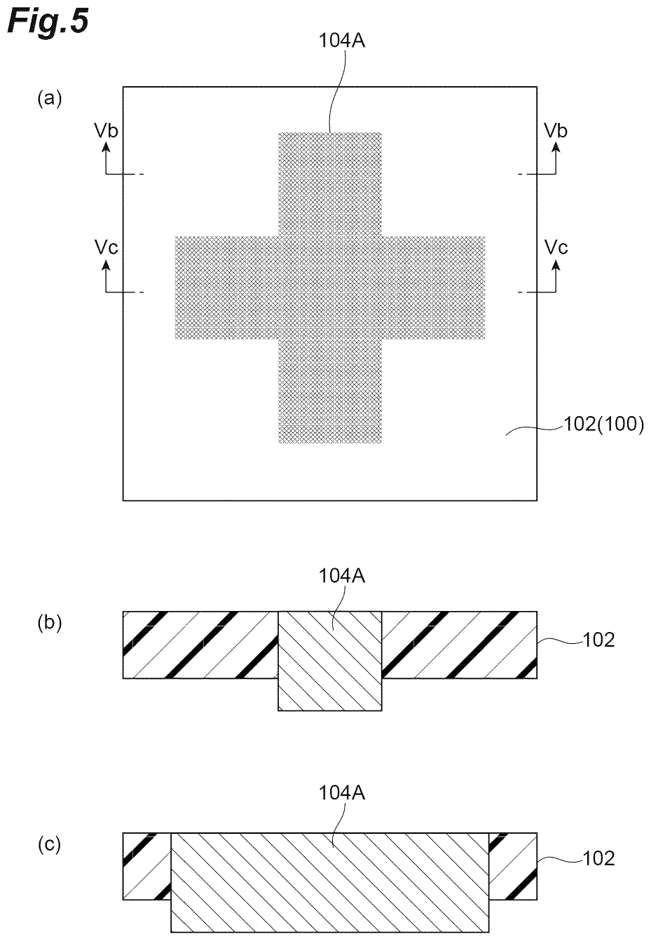

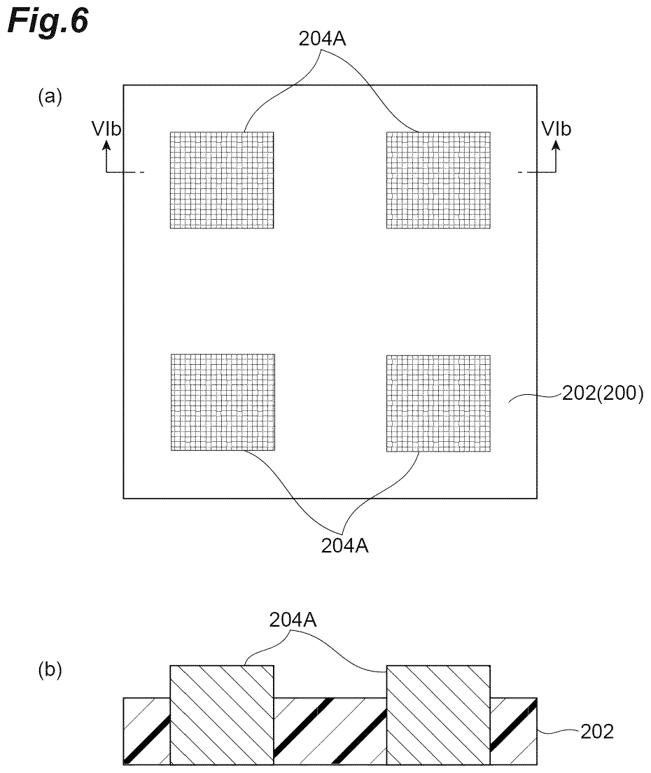

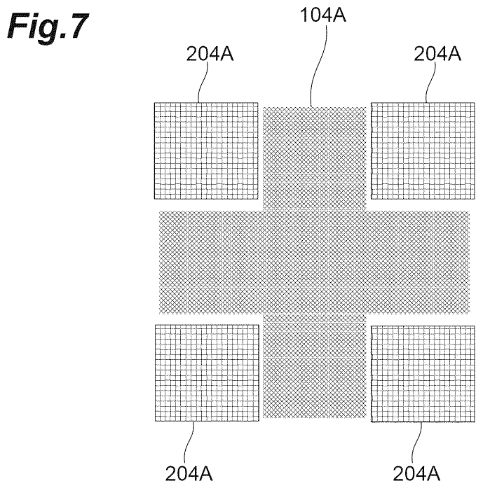

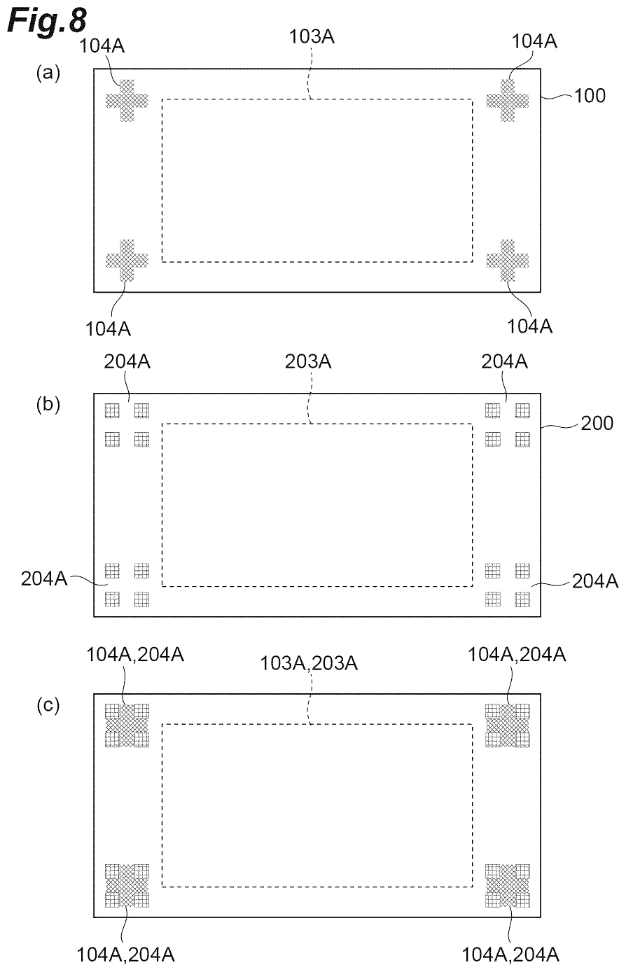

Next, a first modification example of the dummy electrode in the method for manufacturing a semiconductor device according to the present embodiment will be described with reference to FIGS. 5 to 8. Although the dummy electrode according to the first modification example has a different shape and arrangement, the method for manufacturing a semiconductor device using it is the same as that described above, and a detailed description thereof is omitted. (a) of FIG. 5 is a plan view showing a first modification example (alignment mark) of a dummy electrode, (b) of FIG. 5 is a cross-sectional view taken along line Vb-Vb in (a) of FIG. 5, and (c) of FIG. 5 is a cross-sectional view taken along line Vc-Vc in (a) of FIG. 5. (a) of FIG. 6 is a plan view showing an example of a dummy electrode having a shape complementary to the dummy electrode shown in FIG. 5, and (b) of FIG. 6 is a cross-sectional view taken along VIb-VIb in (a) of FIG. 6. FIG. 7 is a plan view showing a state in which the dummy electrode shown in FIG. 5 and the dummy electrode shown in FIG. 6 are overlapped. (a) and (b) of FIG. 8 are plan views showing an example in which the first modification example of the dummy electrodes are provided at the four corners of each semiconductor substrate, and (c) of FIG. 8 is a plan view showing a state in which the dummy electrode shown in (a) of FIG. 8 and the dummy electrodes shown in (b) of FIG. 8 are overlapped.

As shown in (a), (b), and (c) of FIG. 5, a dummy electrode 104A provided on the first semiconductor substrate 100 has, for example, a cross shape. The dummy electrode 104A, like the dummy electrode 104, is formed on the substrate body 101 and protrudes from the insulating film 102. The protrusion height of the dummy electrode 104A is higher than that of the terminal electrode 103 and may be the same as that of the dummy electrode 104. On the other hand, in this first modification example, a dummy electrode 204A (second dummy electrode) corresponding to the dummy electrode 104A is provided on the second semiconductor substrate 200. The dummy electrode 204A, like the dummy electrodes 104 and 104A, is provided on the surface 201a of the substrate body 201 and protrudes from the insulating film 202. The dummy electrode 204A may protrude more than the terminal electrode 203, and for example, may have the same protrusion height as the dummy electrodes 104 and 104A. (a) and (b) of FIG. 6 show such a dummy electrode 204A. The dummy electrode 204A is a collective electrode in which four rectangular portions are arranged apart from each other at equal intervals, and has a shape complementary to the cross-shaped dummy electrode 104A. FIG. 7 shows a state in which such a dummy electrode 104A and a dummy electrode 204A are arranged so as to overlap each other. Such dummy electrodes 104A and 204A can be used as alignment marks, and by overlapping them as shown in FIG. 7, the first semiconductor substrate 100 and the second semiconductor substrate 200 can be positioned.

FIG. 8 shows an example in which four dummy electrodes 104A are arranged at the four corners of the first semiconductor substrate 100, and four corresponding dummy electrodes 204A are arranged at the four corners of the second semiconductor substrate 200. By providing dummy electrodes as alignment marks at the four corners of each substrate in this way, the positioning of the first semiconductor substrate 100 and the second semiconductor substrate 200 can be performed with higher accuracy. In the example shown in FIG. 8, the dummy electrodes 104A and 204A are formed outside the terminal electrode regions 103A and 203A where the plurality of terminal electrodes 103 and 203 are formed.

Thus, in the method for manufacturing a semiconductor device according to the first modification example, in addition to the operational effects of the above-described embodiment, the following operational effects can be achieved. That is, in the first modification example, the dummy electrodes 104A and 204A serve as alignment marks for aligning the terminal electrode 103 and the terminal electrode 203, and the alignment of the first semiconductor substrate 100 and the second semiconductor substrate 200 can be performed using the dummy electrodes. In addition, since a space for individually providing dummy electrodes is not required, the mounting density of wiring electrodes on the semiconductor substrate can be improved.

In the method for manufacturing a semiconductor device according to the first modification example, the second semiconductor substrate 200 has a dummy electrode 204A provided on the surface 201a of the substrate body 201, and the dummy electrode 104A and the dummy electrode 204A have planar shapes that are complementary to each other. By aligning the first semiconductor substrate 100 and the second semiconductor substrate 200 using such a dummy electrode 104A and a dummy electrode 204A, the alignment of both becomes easy.

In the method for manufacturing a semiconductor device according to the first modification example, the insulating film 102 of the first semiconductor substrate 100 is an organic insulating film, and a part of the dummy electrode 204A is configured to be embedded in the insulating film 102, which is an organic insulating film. By thus providing dummy electrodes on each of both semiconductor substrates and configuring them to be embedded in the insulating films, the first semiconductor substrate 100 and the second semiconductor substrate 200 are more reliably bonded to each other, and the manufacturing yield is further improved.

### Second Modification Example

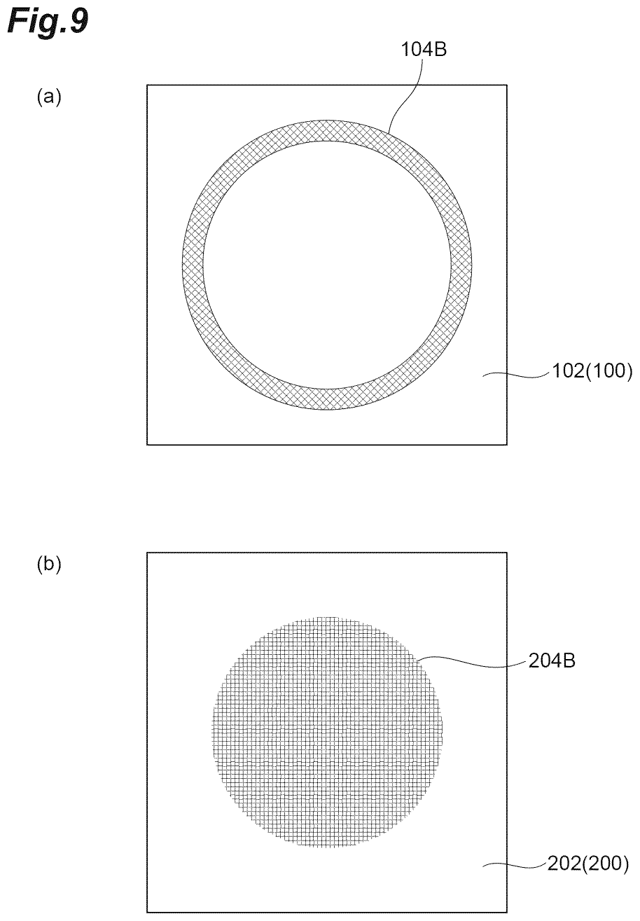

Next, a second modification example of the dummy electrode in the method for manufacturing a semiconductor device according to the present embodiment will be described with reference to FIGS. 9 to 11.

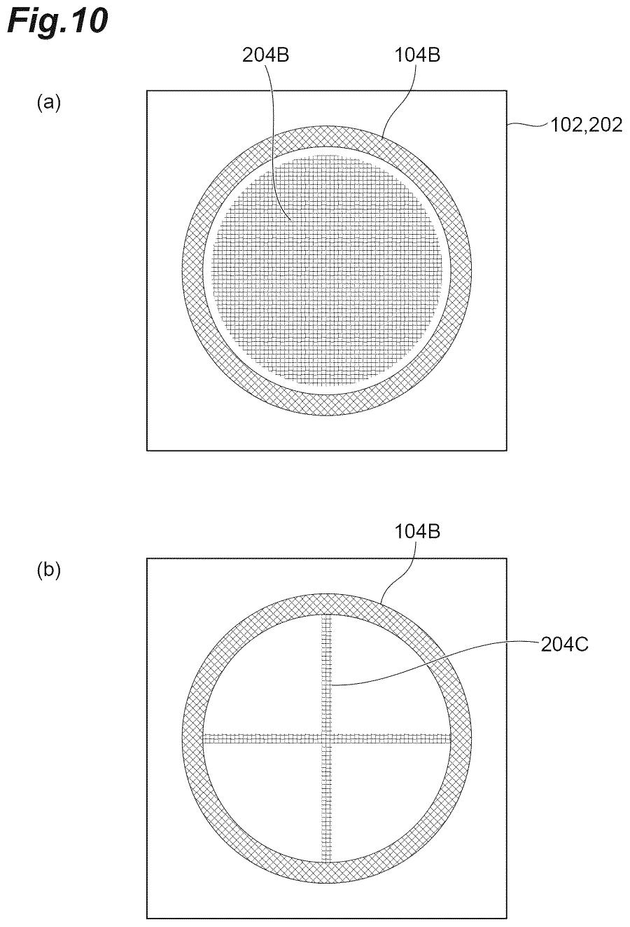

Although the dummy electrode according to the second modification example has a different shape and arrangement, the method for manufacturing a semiconductor device using it is the same as that described above, and a detailed description thereof is omitted. In addition, since the protrusion height and complementary shape of each dummy electrode are the same as in the first modification example, a description thereof is omitted. (a) and (b) of FIG. 9 are plan views showing a second modification example (alignment mark) of a dummy electrode. (a) of FIG. 10 is a plan view showing a state in which the dummy electrode shown in (a) of FIG. 9 and the dummy electrode shown in (b) of FIG. 9 are overlapped. As shown in FIG. 9, in the second modification example, the dummy electrode 104B on the first semiconductor substrate 100 side has a ring shape in a plan view. On the other hand, the dummy electrode 204B on the second semiconductor substrate 200 side has a circular shape in a plan view. The dummy electrode 204B may have a polygonal shape such as a square. Each of the dummy electrodes 104B and 204B protrudes from each insulating film as in the first modification example. Then, as shown in (a) of FIG. 10, when positioning the first semiconductor substrate 100 and the second semiconductor substrate 200, the position of the substrates is adjusted so that the dummy electrode 204B is located inside the dummy electrode 104B. By such alignment, the first semiconductor substrate 100 and the second semiconductor substrate 200 are aligned.

In the second modification example, as in the first modification example, when the first semiconductor substrate 100 and the second semiconductor substrate 200 are bonded, the dummy electrode 104B is embedded in the insulating film 202, and the dummy electrode 204B is embedded in the insulating film 102.

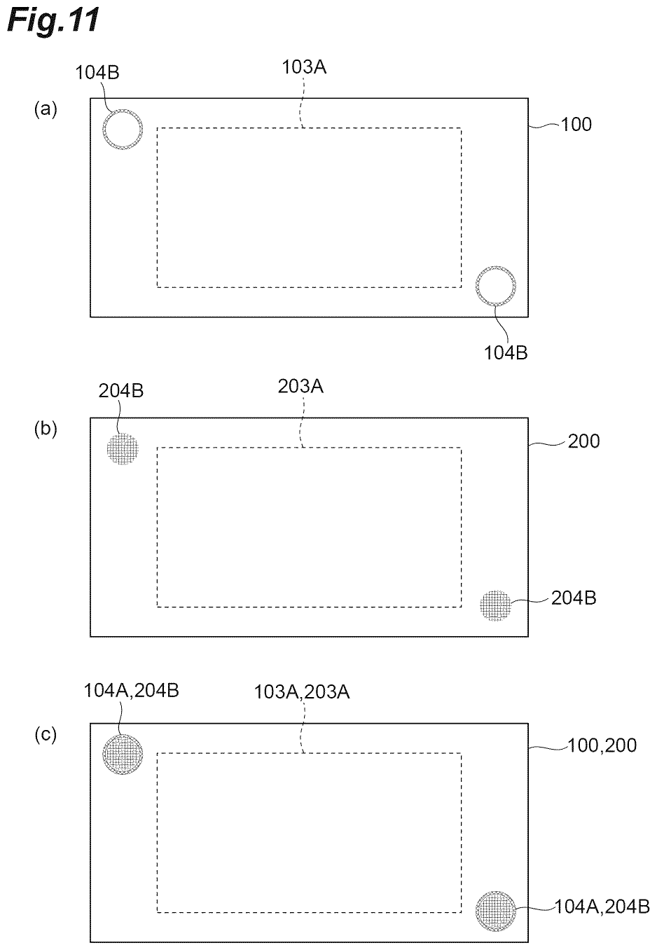

FIG. 11 shows an example in which two dummy electrodes 104B are arranged at two of the four corners (on a diagonal line) of the first semiconductor substrate 100, and two dummy electrodes 204B are arranged at two of the four corners of the second semiconductor substrate 200. By providing dummy electrodes as alignment marks at two locations on each substrate in this way, the positioning of the first semiconductor substrate 100 and the second semiconductor substrate 200 can be performed with higher accuracy. In the example shown in FIG. 11, the dummy electrodes 104B and 204B are formed outside the terminal electrode regions 103A and 203A where the plurality of terminal electrodes 103 and 203 are formed, as in the first modification example.

### Third Modification Example

Next, a third modification example of the dummy electrode in the method for manufacturing a semiconductor device according to the present embodiment will be described with reference to (b) of FIG. 10. Although the dummy electrode according to the third modification example has a different shape and arrangement, the method for manufacturing a semiconductor device using it is the same as that described above, and a detailed description thereof is omitted. (b) of FIG. 10 is a plan view showing a third modification example (alignment mark) of a dummy electrode, and is a plan view showing a state in which the dummy electrode shown in (a) of FIG. 9 and a cross-shaped dummy electrode are overlapped. As shown in (b) of FIG. 10, in the third modification example, the dummy electrode 104B on the first semiconductor substrate 100 side has a ring shape in a plan view, as in the second modification example. On the other hand, the dummy electrode 204C on the second semiconductor substrate 200 side has a cross shape in a plan view. Then, as shown in (b) of FIG. 10, when positioning the first semiconductor substrate 100 and the second semiconductor substrate 200, the position of the substrates is adjusted so that the dummy electrode 204C is located inside the dummy electrode 104B.

Although the embodiments and modification examples of the method for manufacturing a semiconductor device and the semiconductor device according to the present disclosure have been described in detail above, the present invention is not limited to the above-described embodiments and modification examples, and can be applied to various embodiments and modification examples. For example, in the above description, the insulating film 202 had a flat shape as a whole, but it is not limited to this. For example, in the method for manufacturing a semiconductor device according to the present embodiment, a region of the insulating film 202 facing the dummy electrode 104 may be formed to be thicker than other regions of the insulating film 202. For example, the surface of the insulating film 202 may be roughened and made thicker by irradiating the facing region with argon ions. This allows the dummy electrode 104 to contact the insulating film 202 earlier, and the dummy electrode 104 is reliably embedded in the insulating film 202. Therefore, according to this manufacturing method, the first semiconductor substrate 100 and the second semiconductor substrate 200 are reliably bonded, and the manufacturing yield is improved.

### REFERENCE SIGNS LIST

1 . . . semiconductor device, 10, 100 . . . first semiconductor substrate, 11, 101 . . . substrate body (first substrate body), 12, 102 . . . insulating film (first insulating film), 13, 103 . . . terminal electrode (first electrode), 14, 104, 104A, 104B . . . dummy electrode (first dummy electrode), 20, 200 . . . second semiconductor substrate, 21, 201 . . . substrate body (second substrate body), 22, 202 . . . insulating film (second insulating film), 23, 203 . . . terminal electrode (second electrode), 204A, 204B, 204C . . . dummy electrode (second dummy electrode).

1. A method for manufacturing a semiconductor device, comprising:
preparing a first semiconductor substrate including a first substrate body, a first insulating film provided on a surface of the first substrate body, and at least one first electrode and at least one first dummy electrode that are provided on the surface of the first substrate body;
preparing a second semiconductor substrate including a second substrate body, a second insulating film provided on a surface of the second substrate body, and at least one second electrode provided on the surface of the second substrate body;
arranging the first semiconductor substrate and the second semiconductor substrate such that the first insulating film and the second insulating film face each other and the first electrode and the second electrode are aligned;
bonding the first insulating film and the second insulating film to each other; and
bonding the first electrode and the second electrode to each other,
wherein the second insulating film is an organic insulating film, and
wherein the first dummy electrode is configured to be at least partially embedded in the second insulating film.

2. The method for manufacturing a semiconductor device according to claim 1,
wherein a protrusion height of the first dummy electrode from a surface of the first insulating film is greater than a first protrusion height of the first electrode from the surface of the first insulating film.

3. The method for manufacturing a semiconductor device according to claim 1,
wherein a protrusion height of the first dummy electrode from a surface of the first insulating film is equal to or greater than a sum of a first protrusion height of the first electrode from the surface of the first insulating film and a second protrusion height of the second electrode from a surface of the second insulating film.

4. The method for manufacturing a semiconductor device according to claim 1,
wherein a protrusion height of the first dummy electrode from a surface of the first insulating film is smaller than a thickness of the second insulating film.

5. The method for manufacturing a semiconductor device according to claim 1,
wherein a protrusion height of the first dummy electrode from a surface of the first insulating film is from 0.02 μm to 5 μm.

6. The method for manufacturing a semiconductor device according to claim 1,
wherein, in the aligning the first electrode and the second electrode, the first dummy electrode contacts the second insulating film before the first electrode and the second electrode contact each other.

7. The method for manufacturing a semiconductor device according to claim 1,
wherein, in the preparing the first semiconductor substrate, the first dummy electrode is formed from the same metal material as the first electrode, and the first electrode and the first dummy electrode are polished such that the first dummy electrode protrudes more than the first electrode.

8. The method for manufacturing a semiconductor device according to claim 1,
wherein, in the preparing the first semiconductor substrate, a metal material is added on a main body of the first dummy electrode such that the first dummy electrode protrudes more than the first electrode.

9. The method for manufacturing a semiconductor device according to claim 1,
wherein a region of the second insulating film facing the first dummy electrode is formed to be thicker than other regions of the second insulating film.

10. The method for manufacturing a semiconductor device according to claim 1,
wherein the at least one first dummy electrode comprises a plurality of dummy electrodes.

11. The method for manufacturing a semiconductor device according to claim 10,
wherein the at least one first electrode comprises a plurality of first electrodes, and the plurality of first electrodes are located between the plurality of dummy electrodes.

12. The method for manufacturing a semiconductor device according to claim 1,
wherein the first dummy electrode is an alignment mark configured to align the first electrode and the second electrode.

13. The method for manufacturing a semiconductor device according to claim 1,
wherein a planar shape of the first dummy electrode is a cross shape, a ring shape, a circular shape, or a polygonal shape.

14. The method for manufacturing a semiconductor device according to claim 1,
wherein the second semiconductor substrate comprises at least one second dummy electrode provided on the surface of the second substrate body, and the first dummy electrode and the second dummy electrode have planar shapes that are complementary to each other.

15. The method for manufacturing a semiconductor device according to claim 14,
wherein the first insulating film of the first semiconductor substrate is an organic insulating film, and
wherein the second dummy electrode is configured to be at least partially embedded in the first insulating film.

16. A semiconductor device, comprising:
a first semiconductor substrate comprising a first substrate body, a first insulating film provided on a surface of the first substrate body, and at least one first electrode and at least one first dummy electrode that are provided on the surface of the first substrate body; and
a second semiconductor substrate comprising a second substrate body, a second insulating film provided on a surface of the second substrate body, and at least one second electrode provided on the surface of the second substrate body,
wherein the first insulating film and the second insulating film are bonded to each other, and the first electrode and the second electrode are bonded to each other,
wherein the second insulating film is an organic insulating film, and the first dummy electrode is configured to be at least partially embedded in the second insulating film.
